(19) United States
(12) Patent Application Publication
(10) Pub. No.: US 2024/0065066 A1
(43) Pub. Date: Feb. 22, 2024

(54) DISPLAY PANEL AND DISPLAY DEVICE

(71) Applicant: Wuhan Tianma Micro-Electronics Co., Ltd., Wuhan (CN)

(72) Inventor: Wei HUANG, Wuhan (CN)

(21) Appl. No.: 18/091,046

(22) Filed: Dec. 29, 2022

(30) Foreign Application Priority Data
Aug. 18, 2022 (CN) 202210993027.X

(51) Int. Cl. H10K 59/35

(52) U.S. Cl. CPC H10K 59/353; H10K 59/352; H10K 59/122

(57) ABSTRACT

A display panel and a display device are provided. The display panel includes a plurality of scanning lines, a plurality of data lines, and a plurality of pixel units arranged in an array along a first direction and a second direction. A pixel unit includes a first-color sub-pixel, a second-color sub-pixel and a third-color sub-pixel. Each of the first-color sub-pixel, the second-color sub-pixel and the third-color sub-pixel has a polygon shape with a longest edge. The longest edges of the first-color sub-pixel and the second-color sub-pixel are away from a geometric center of the pixel unit, and are extended along the second direction and the first direction, respectively. The longest edge of the third-color sub-pixel is close to the geometric center of the pixel unit, and is extended along a direction intersecting the first direction and the second direction.

### CROSS-REFERENCE TO RELATED APPLICATION

This application claims the priority of Chinese patent application No. 202210993027.X, filed on Aug. 18, 2022, the entirety of which is incorporated herein by reference.

### FIELD

The present disclosure generally relates to the field of display technology and, more particularly, relates to a display panel and a display device.

### BACKGROUND

An organic light-emitting diode (OLED) is a diode that utilizes the reversible color change of an organic semiconducting material driven by an electric current to achieve display. A basic structure of an OLED display device often includes an anode, a light-emitting layer and a cathode. When an appropriate voltage is supplied from a power source, holes from the anode and electrons from the cathode combine in the light-emitting layer to produce bright light. Compared with the thin film field effect transistor liquid crystal display, the OLED display device has advantages of high visibility, high brightness, power-saving, light weight and thin thickness. Therefore, the OLED display device is regarded as one of the most promising products in the display industry.

At present, for realizing color display in OLED display technology, full-color technology is often used based on light-emitting from independent pixels of three primary colors (RGB). How to carry out reasonable arrangement of pixels in display products to further improve the display quality of display products is one of the research trends in the display field at current stage.

### SUMMARY

One aspect of the present disclosure provides a display panel. The display panel includes a plurality of scanning lines and a plurality of data lines. The plurality of scanning lines are extended along a first direction and arranged along a second direction, the plurality of data lines are extended along the second direction and arranged along the first direction, and the first direction intersects the second direction. The display panel also includes a plurality of pixel units arranged in an array along the first direction and the second direction. A pixel unit of the plurality of pixel units includes three sub-pixels, the three sub-pixels include a first-color sub-pixel, a second-color sub-pixel and a third-color sub-pixel, respectively, and the first color, the second color and the third color are different from each other. A pixel opening area of the third-color sub-pixel is larger than a pixel opening area of the first-color sub-pixel, and is larger than a pixel opening area of the second-color sub-pixel. Along the first direction, the third-color sub-pixel overlaps with the first-color sub-pixel and does not overlap with the second-color sub-pixel, and along the second direction, the third-color sub-pixel overlaps with the second-color sub-pixel and does not overlap with the first-color sub-pixel. Each of the first-color sub-pixel, the second-color sub-pixel and the third-color sub-pixel has a polygon shape with a longest edge. An extension direction of the longest edge of the first-color sub-pixel is along the second direction, an extension direction of the longest edge of the second-color sub-pixel is along the first direction, and an extension direction of the longest edge of the third-color sub-pixel intersects the first direction and the second direction. The longest edge of the first-color sub-pixel is located on a side of other edges of the first-color sub-pixel facing away from a geometric center of a region where the pixel unit is located, the longest edge of the second-color sub-pixel is located on a side of other edges of the second-color sub-pixel facing away from the geometric center of the region where the pixel unit is located, and the longest edge of the third-color sub-pixel is located on a side of other edges of the third-color sub-pixel facing towards the geometric center of the region where the pixel unit is located.

Another aspect of the present disclosure provides a display device. The display device includes a display panel. The display panel includes a plurality of scanning lines and a plurality of data lines. The plurality of scanning lines are extended along a first direction and arranged along a second direction, the plurality of data lines are extended along the second direction and arranged along the first direction, and the first direction intersects the second direction. The display panel also includes a plurality of pixel units arranged in an array along the first direction and the second direction. A pixel unit of the plurality of pixel units includes three sub-pixels, the three sub-pixels include a first-color sub-pixel, a second-color sub-pixel and a third-color sub-pixel, respectively, and the first color, the second color and the third color are different from each other. A pixel opening area of the third-color sub-pixel is larger than a pixel opening area of the first-color sub-pixel, and is larger than a pixel opening area of the second-color sub-pixel. Along the first direction, the third-color sub-pixel overlaps with the first-color sub-pixel and does not overlap with the second-color sub-pixel, and along the second direction, the third-color sub-pixel overlaps with the second-color sub-pixel and does not overlap with the first-color sub-pixel. Each of the first-color sub-pixel, the second-color sub-pixel and the third-color sub-pixel has a polygon shape with a longest edge. An extension direction of the longest edge of the first-color sub-pixel is along the second direction, an extension direction of the longest edge of the second-color sub-pixel is along the first direction, and an extension direction of the longest edge of the third-color sub-pixel intersects the first direction and the second direction. The longest edge of the first-color sub-pixel is located on a side of other edges of the first-color sub-pixel facing away from a geometric center of a region where the pixel unit is located, the longest edge of the second-color sub-pixel is located on a side of other edges of the second-color sub-pixel facing away from the geometric center of the region where the pixel unit is located, and the longest edge of the third-color sub-pixel is located on a side of other edges of the third-color sub-pixel facing towards the geometric center of the region where the pixel unit is located.

Other aspects of the present disclosure can be understood by those skilled in the art in light of the description, the claims, and the drawings of the present disclosure.

### BRIEF DESCRIPTION OF THE DRAWINGS

To more clearly illustrate the embodiments of the present disclosure, the drawings will be briefly described below. The drawings in the following description are certain embodiments of the present disclosure, and other drawings may be obtained by a person of ordinary skill in the art in view of the drawings provided without creative efforts.

FIG. 1 illustrates a schematic diagram of arrangement of pixels of a display panel;

FIG. 2 illustrates a schematic diagram of an exemplary display panel consistent with disclosed embodiments of the present disclosure;

FIG. 3 illustrates a schematic diagram of arrangement of pixels of an exemplary display panel consistent with disclosed embodiments of the present disclosure;

FIG. 4 illustrates a schematic diagram of arrangement of pixels of another exemplary display panel consistent with disclosed embodiments of the present disclosure;

FIG. 5 illustrates a schematic diagram of arrangement of pixels of another exemplary display panel consistent with disclosed embodiments of the present disclosure;

FIG. 6 illustrates a schematic diagram of arrangement of pixels of another exemplary display panel consistent with disclosed embodiments of the present disclosure;

FIG. 7 illustrates a schematic diagram of arrangement of three sub-pixels in a same pixel unit in an exemplary display panel consistent with disclosed embodiments of the present disclosure;

FIG. 8 illustrates a schematic diagram of arrangement of pixels of another exemplary display panel consistent with disclosed embodiments of the present disclosure;

FIG. 9 illustrates a schematic diagram of arrangement of pixels of another exemplary display panel consistent with disclosed embodiments of the present disclosure;

FIG. 10 illustrates a schematic diagram of arrangement of pixels of another exemplary display panel consistent with disclosed embodiments of the present disclosure;

FIG. 11 illustrates a schematic diagram of arrangement of pixels of another exemplary display panel consistent with disclosed embodiments of the present disclosure;

FIG. 12 illustrates a schematic diagram of arrangement of pixels of another exemplary display panel consistent with disclosed embodiments of the present disclosure;

FIG. 13 illustrates a schematic diagram of film layers of an exemplary display panel consistent with disclosed embodiments of the present disclosure;

FIG. 14 illustrates a schematic diagram of arrangement of pixels of another exemplary display panel consistent with disclosed embodiments of the present disclosure;

FIG. 15 illustrates a schematic diagram of film layers of another exemplary display panel consistent with disclosed embodiments of the present disclosure;

FIG. 16 illustrates a schematic diagram of film layers of another exemplary display panel consistent with disclosed embodiments of the present disclosure;

FIG. 17 illustrates a schematic top view of sub-pixels and data lines in an exemplary display panel consistent with disclosed embodiments of the present disclosure;

FIG. 18 illustrates a schematic top view of sub-pixels and data lines in another exemplary display panel consistent with disclosed embodiments of the present disclosure;

FIG. 19 illustrates a schematic diagram of arrangement of sub-pixels in a same pixel unit in another exemplary display panel consistent with disclosed embodiments of the present disclosure; and

FIG. 20 illustrates a schematic diagram of an exemplary display device consistent with disclosed embodiments of the present disclosure.

### DETAILED DESCRIPTION OF THE DISCLOSURE

Reference will now be made in detail to exemplary embodiments of the disclosure, which are illustrated in the accompanying drawings. Wherever possible, the same reference numbers will be used throughout the drawings to refer to the same or the alike parts. The described embodiments are some but not all of the embodiments of the present disclosure. Based on the disclosed embodiments, persons of ordinary skill in the art may derive other embodiments consistent with the present disclosure, all of which are within the scope of the present disclosure.

Similar reference numbers and letters represent similar terms in the following Figures, such that once an item is defined in one Figure, it does not need to be further discussed in subsequent Figures.

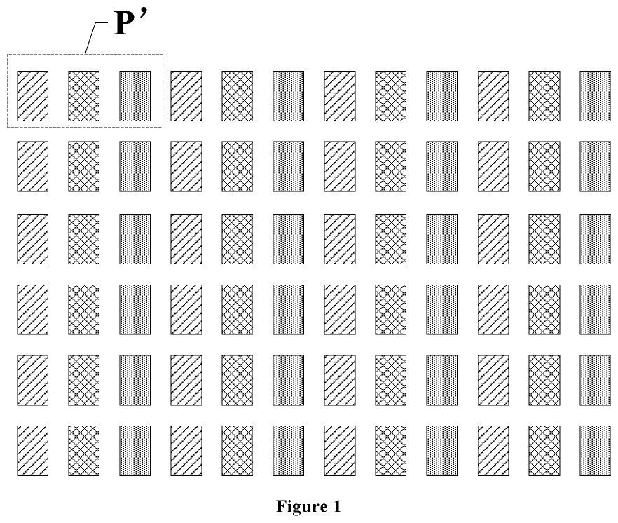

FIG. 1 illustrates a schematic diagram of arrangement of pixels of a display panel. Referring to FIG. 1, the display panel includes a plurality of pixel units P′. Each pixel unit P′ includes three pixels with different colors, and the three pixels in a same pixel unit P′ are located in a same pixel row. For such arrangement structure of pixels, because the arrangement manner is simple, the manufacturing process is substantially simple. However, for a display panel with such arrangement structure of pixels, an aperture ratio is low, such that a screen-to-body ratio and display quality cannot be further improved.

The present disclosure provides a display panel. The display panel may include a plurality of scan lines and a plurality of data lines. The scan lines may be extended along a first direction and may be arranged along a second direction. The data lines may be extended along the second direction and may be arranged along the first direction. The first direction may intersect the second direction. The display panel may further include a plurality of pixel units arranged in an array along the first direction and the second direction. A same pixel unit may include three sub-pixels, and the three sub-pixels may include a first-color sub-pixel, a second-color sub-pixel and a third-color sub-pixel, respectively. The first color, the second color and the third color may be different from each other. A pixel opening area of the third-color sub-pixel may be larger than a pixel opening area of the first-color sub-pixel, and may be larger than a pixel opening area of the second-color sub-pixel.

Along the first direction, the third-color sub-pixel may overlap with the first-color sub-pixel and may not overlap with the second-color sub-pixel. Along the second direction, the third-color sub-pixel may overlap with the second-color sub-pixel and may not overlap with the first-color sub-pixel. Each of the first-color sub-pixel, the second-color sub-pixel and the third-color sub-pixel may have a polygon shape with a longest edge. An extension direction of the longest edge of the first-color sub-pixel may be along the second direction, an extension direction of the longest edge of the second-color sub-pixel may be along the first direction, and an extension direction of the longest edge of the third-color sub-pixel may intersect the first direction and the second direction.

The longest edge of the first-color sub-pixel may be located on a side of the other edges of the first-color sub-pixel away from a geometric center of the region where the pixel unit is located. The longest edge of the second-color sub-pixel may be located on a side of the other edges of the second-color sub-pixel away from the geometric center of the region where the pixel unit is located. The longest edge of the third-color sub-pixel may be located on a side of the other edges of the third-color sub-pixel facing towards the geometric center of the region where the pixel unit is located. By changing the arrangement structure of sub-pixels, an aperture ratio of the display panel may be effectively improved, which may facilitate to improve the screen-to-body ratio and display quality of the display panel.

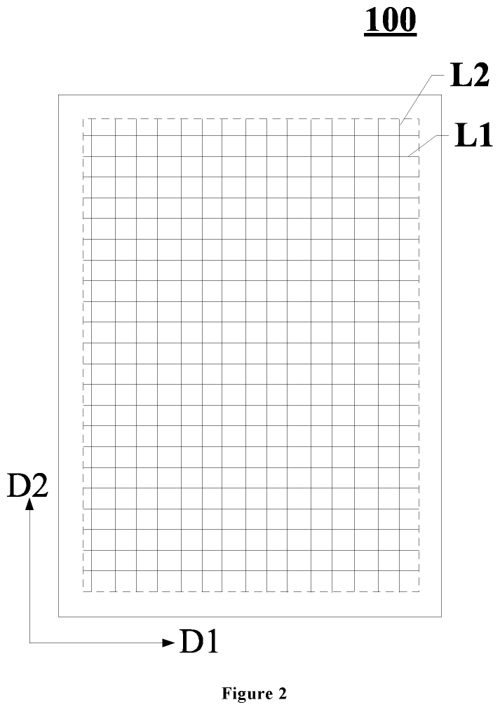

FIG. 2 illustrates a schematic diagram of a display panel consistent with disclosed embodiments of the present disclosure; and FIG. 3 illustrates a schematic diagram of arrangement of pixels of the display panel consistent with disclosed embodiments of the present disclosure. Referring to FIG. 2 and FIG. 3, a display panel 100 may include a plurality of scan lines L1 and a plurality of data lines L2. The scan lines L1 may be extended along a first direction D1 and may be arranged along a second direction D2, and the data lines L2 may be extended along the second direction D2 and may be arranged along the first direction D1. The first direction D1 may intersect the second direction D2.

The display panel 100 may further include a plurality of pixel units P arranged in an array along the first direction D1 and the second direction D2. A same pixel unit P may include three sub-pixels, and the three sub-pixels may include a first-color sub-pixel P1, a second-color sub-pixel P2, and a third-color sub-pixel P3, respectively. The first color, the second color and the third color may be different from each other. A pixel opening area of the third-color sub-pixel P3 may be larger than a pixel opening area of the first-color sub-pixel P1, and may be larger than a pixel opening area of the second-color sub-pixel P2.

Along the first direction D1, the third-color sub-pixel P3 may overlap with the first-color sub-pixel P1 and may not overlap with the second-color sub-pixel P2. Along the second direction D2, the third-color sub-pixel P3 may overlap with the second-color sub-pixel P2 and may not overlap with the first-color sub-pixel P1. The first-color sub-pixel P1, the second-color sub-pixel P2 and the third-color sub-pixel P3 may have a polygon shape, and each of the first-color sub-pixel P1, the second-color sub-pixel P2 and the third-color sub-pixel P3 may have a longest edge. An extension direction of the longest edge of the first-color sub-pixel P1 may be along the second direction D2, an extension direction of the longest edge of the second-color sub-pixel P2 may be along the first direction D1, and an extension direction of the longest edge of the third-color sub-pixel P3 may intersect the first direction D1 and the second direction D2.

The longest edge of the first-color sub-pixel P1 may be located on a side of the other edges of the first-color sub-pixel P1 away from a geometric center of the region where the pixel unit P is located. The longest edge of the second-color sub-pixel P2 may be located on a side of the other edges of the second-color sub-pixel P2 away from the geometric center of the region where the pixel unit P is located. The longest edge of the third-color sub-pixel P3 may be located on a side of the other edges of the third-color sub-pixel P3 facing towards the geometric center of the region where the pixel unit P is located.

Specifically, the disclosed display panel may include a display panel using the organic light-emitting diode display technology. In the disclosed display panel, the arrangement structure of pixels may be improved, and the same pixel unit P may include three sub-pixels with different emission colors. The pixel opening area of the third-color sub-pixel P3 may be larger than the pixel opening areas of both the first-color sub-pixel P1 and the second-color sub-pixel P2. Along the first direction D1, the third-color sub-pixel P3 may overlap with the first-color sub-pixel P1, and may not overlap with the second-color sub-pixel P2. Along the second direction D2, the third-color sub-pixel P3 may overlap with the second-color sub-pixel P2 and may not overlap with the first-color sub-pixel P1. In view of such arrangement, the arrangement of the three sub-pixels in the same pixel unit P may be substantially compact. Compared with the arrangement where the three sub-pixels in the pixel unit P are arranged in a same column or in a same row, the disclosed arrangement of sub-pixels may improve the aperture ratio and screen-to-body ratio of the display panel, and may further facilitate to improve the display quality.

In addition, in the same pixel unit P, each sub-pixel may include a longest edge. The extension direction of the longest edge of the first-color sub-pixel P1 may be along the second direction D2, and the longest edge of the first-color sub-pixel P1 may be located on the side of the other edges of the first-color sub-pixel P1 away from the geometric center of the region where the pixel unit P is located. The extension direction of the longest edge of the second-color sub-pixel P2 may be along the first direction D1, and the longest edge of the second-color sub-pixel P2 may be located on the side of the other edges of the second-color sub-pixel P2 away from the geometric center of the region where the pixel unit P is located. The extension direction of the longest edge of the third-color sub-pixel P3 may intersect the first direction D1 and the second direction D2, and the longest edge of the third-color sub-pixel P3 may be located on the side of the other edges of the third-color sub-pixel P3 facing towards the geometric center of the region where the pixel unit P is located. In such arrangement, the longest edge of the first-color sub-pixel P1, the longest edge of the second-color sub-pixel P2, and the other edges except for the longest edge of the third-color sub-pixel P3 may together form an outline of the pixel unit P. Such arrangement may also facilitate to improve the arrangement compactness of the three sub-pixels of the pixel unit P, which may facilitate to further improve the aperture ratio and screen-to-body ratio of the display panel, thereby further improving the display quality.

It should be noted that FIG. 3 may merely use the outlines of the three sub-pixels as triangles as an example for illustration. In one embodiment, the pixel unit P formed by the sub-pixels with the triangular structure may be used as an example. The geometric center of the region where the pixel unit P is located may be regarded as the geometric center of the outline of the pixel unit P formed by the longest edge of the first-color sub-pixel P1, the longest edge of the second-color sub-pixel P2 and the other edges except for the longest edge of the third-color sub-pixel P3. In the arrangement structure shown in FIG. 3, for illustrative purposes, the outline of the pixel unit P may be a rectangle as an example, while the actual shape of the pixel unit P may not be limited by the present disclosure.

It should be noted that FIG. 2 in the disclosed embodiments may merely illustrate the structure of the display panel. In specific implementation, the structure of the display panel may further include any other structure, such as the film layer structure, a pixel circuit, a driving circuit, a packaging structure, etc., which may not be repeated herein and may be understood with reference to the structure of the organic light-emitting diode display panel in the related art. Moreover, for illustrative purposes, FIG. 2 may merely use the display panel with a rectangular shape as an example. In certain embodiments, the display panel may include any other shape, such as a rounded rectangle, a circle, an oval or any other feasible shape.

It should be further noted that the figures in the disclosed embodiments may merely illustrate the size and shapes of the pixel unit P and the three sub-pixels of the pixel unit P. In specific implementation, the pixel unit P and the three sub-pixels of the pixel unit P may include but may not be limited to the size and shapes shown in FIG. 3, and may include any other size and shape, which may not be limited by the present disclosure.

Referring to FIG. 3, in one embodiment, in the same pixel unit P, the first-color sub-pixel P1, the second-color sub-pixel P2 and the third-color sub-pixel P3 may have a convex polygon shape.

When any edge of a convex polygon is infinitely extended to two sides into a straight line, other edges of the convex polygon may be located on a same side of the straight line. Therefore, when the sub-pixel of the pixel unit P is designed as a convex polygon structure, the sub-pixel may have a substantially regular shape, which may not only improve the arrangement compactness of the three sub-pixels of the pixel unit P, but also facilitate to ensure the opening area of the sub-pixels and to simplify the manufacturing process of the sub-pixels.

Referring to FIG. 3, in one embodiment, the three sub-pixels of the same pixel unit P may have a same shape.

In the embodiment associated with FIG. 3, for illustrative purposes, the three sub-pixels of the pixel unit P may have a triangle shape as an example, and the actual shape of the sub-pixel may not be limited. In certain embodiments, the three sub-pixels in the same pixel unit P may include any other shape, which may be described in subsequent embodiments. The three sub-pixels of the same pixel unit P may have the same shape, which may facilitate to simplify the structure of the mask required for forming the sub-pixels, and, thus, may facilitate to simplify the fabrication process of the mask. In addition, when the three sub-pixels of the same pixel unit P have the same shape, the overall arrangement complexity of pixels of the display panel may be simplified.

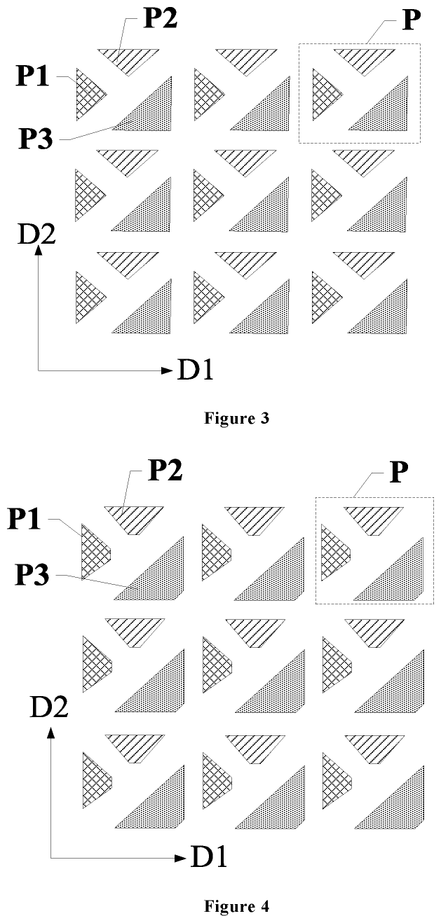

FIG. 4 illustrates a schematic diagram of arrangement of pixels of another display panel consistent with disclosed embodiments of the present disclosure; and FIG. 5 illustrates a schematic diagram of arrangement of pixels of another display panel consistent with disclosed embodiments of the present disclosure. In one embodiment, the three sub-pixels of the same pixel unit P may have any one of a triangle shape, a trapezoid shape, and a hexagon shape.

The embodiment associated with FIG. 3 provides a solution in which the three sub-pixels of the same pixel unit P may have a triangular shape. The embodiment associated with FIG. 4 provides a solution in which the three sub-pixels of the same pixel unit P may have a trapezoidal shape. The embodiment associated with FIG. 5 provides a solution in which the three sub-pixels of the same pixel unit P may have a hexagonal shape. On the premise of ensuring that the pixel opening area of the third-color sub-pixel P3 is the largest, in the disclosed embodiments, the sub-pixels of the pixel unit P may have a triangular shape, a trapezoidal shape or a hexagonal shape, and the shape may be substantially regular, which may facilitate to reduce the manufacturing process of the mask, and at the same time, may facilitate to simplify the evaporation process of the sub-pixels.

It should be noted that FIGS. 3-5 may merely illustrate the solution in which the three sub-pixels of the same pixel unit P may have a same shape. In certain embodiments, the shape of the three sub-pixels of the same pixel unit P may be different from each other, or merely two of the three sub-pixels may have a same shape, which may not be limited by the present disclosure.

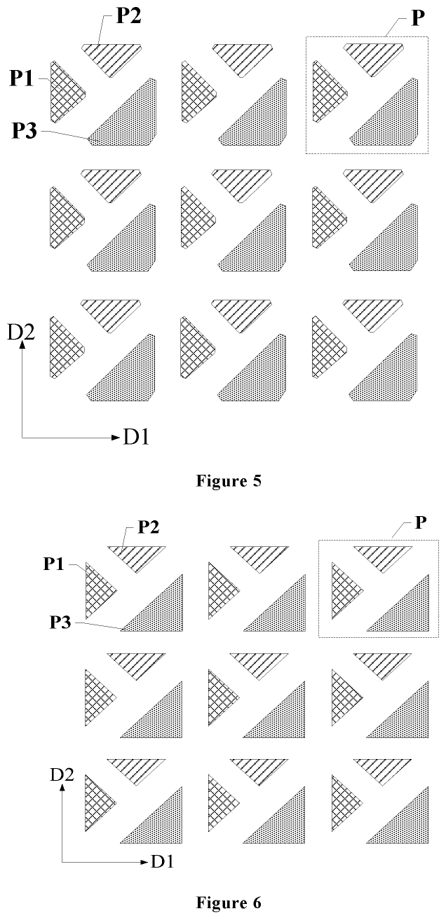

FIG. 6 illustrates a schematic diagram of arrangement of pixels of another display panel consistent with disclosed embodiments of the present disclosure. Referring to FIG. 6, the three sub-pixels of the same pixel unit P may have an isosceles right triangular shape.

In one embodiment, when the sub-pixel has an isosceles right triangular shape, the corner space in the pixel unit P may be reasonably utilized. Compared with the solution in which the corner space in the pixel unit P is difficult to vaporize the sub-pixels, the disclosed embodiments may facilitate to increase the aperture ratio of the sub-pixels of the pixel unit P, may facilitate to increase the overall aperture ratio of the display panel, and may further facilitate to improve the overall display quality of the display panel.

FIG. 7 illustrates a schematic diagram of arrangement of three sub-pixels of the same pixel unit P. Referring to FIG. 7, in one embodiment, in the same pixel unit P, at least a portion of the sub-pixels may include a first edge E01 and a second edge E02 that are disposed parallel to each other, a first side waist Y01 and a second side waist Y02 that are respectively connected with two ends of the first edge E01, and a first connecting edge L01 and a second connecting edge L02. The first connecting edge L01 may connect the first side waist Y01 and the first end of the second edge E02, and the second connecting edge L02 may connect the second side waist Y02 and the second end of the second edge E02. The second edge E02 may be the longest edge of the sub-pixel.

The embodiment associated with FIG. 7 illustrates a schematic diagram of a detailed structure of the sub-pixel when the sub-pixel of the pixel unit P has a hexagonal shape. The hexagonal shape may be regarded as a shape obtained by cutting three corners of a triangle shape. Considering the manufacturing process of the mask, compared with the mask opening with the triangular structure, when the mask opening matches the shape of the sub-pixel in FIG. 7, the manufacturing process of the mask with such structure may be substantially simple.

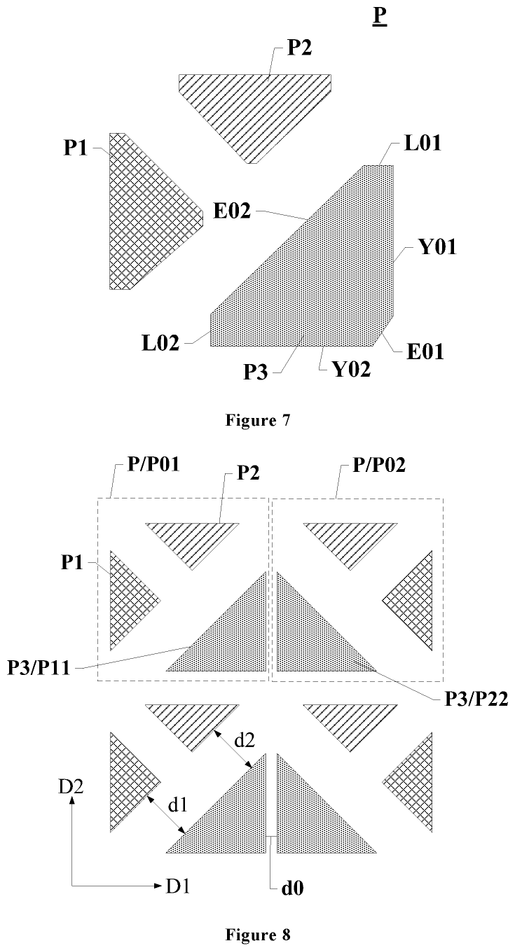

FIG. 8 illustrates a schematic diagram of arrangement of pixels of another display panel consistent with disclosed embodiments of the present disclosure; and FIG. 9 illustrates a schematic diagram of arrangement of pixels of another display panel consistent with disclosed embodiments of the present disclosure. In one embodiment, referring to FIG. 8, the sub-pixels in the adjacent two pixel units P along the first direction D1 may be arranged in a mirror image. In another embodiment, referring to FIG. 9, the sub-pixels in the adjacent two pixel units P along the second direction D2 may be arranged in a mirror image. The third-color sub-pixels P3 in the two pixel units P that are arranged in a mirror image may be adjacent to each other.

The embodiment associated with FIG. 8 illustrates a solution in which the sub-pixels in adjacent two pixel units P along the first direction D1 may be arranged in a mirror image, and the embodiment associated with FIG. 9 illustrates a solution in which the sub-pixels in adjacent two pixel units P along the second direction D2 may be arranged in a mirror image. In the two embodiments associated with FIGS. 8-9, the third-color sub-pixels P3 in the two pixel units P arranged in a mirror image may be adjacent to each other. In other words, the two third-color sub-pixels P3 with the largest pixel opening area in the two pixel units P arranged in a mirror image may be adjacent to each other. In view of this, the adjacent two third-color sub-pixels P3 may share a same opening of the mask for vapor deposition, which may facilitate to reduce the number of openings of the metal mask used in the manufacturing process, and may avoid the reduction of the strength of the metal mask caused by the excessive number of openings and the too small size, thereby improving the strength of the metal mask.

Referring to FIG. 8 and FIG. 9, in another embodiment, the sub-pixels in adjacent two pixel units P along the first direction D1 may be arranged in a mirror image, and/or the sub-pixels in adjacent two pixel units P along the second direction D2 may be arranged in a mirror image. The two pixel units P that are arranged in a mirror image may include a first pixel unit P01 and a second pixel unit P02, respectively. The first sub-pixel P11 in the first pixel unit P01 may be adjacent to the second sub-pixel P22 in the second pixel unit P02. A width of the interval between the first sub-pixel P11 and the second sub-pixel P22 may be smaller than a width of the interval between the first sub-pixel P11 and any other sub-pixel in the first pixel unit P01, and may be smaller than a width of the interval between the second sub-pixel P22 and any other sub-pixel in the second pixel unit P02. In one embodiment, the first sub-pixel P11 and the second sub-pixel P22 may have a same color.

For illustrative purposes, in the embodiments associated with FIG. 8 and FIG. 9, the first sub-pixel P11 and the second sub-pixel P22 may be the third-color sub-pixel P3 as an example. In certain embodiments, the first sub-pixel P11 and the second sub-pixel P22 may be the first-color sub-pixel P1 or the second-color sub-pixel P2, which may not be limited by the present disclosure.

Referring to FIG. 8 and FIG. 9, the first sub-pixel P11 and the second sub-pixel P22 may be the third-color sub-pixel P3 as an example. In the two pixel units P that are arranged in a mirror image, the width of the interval d0 between the adjacent third-color sub-pixels P3 may be smaller than the width of the interval d1 between the third-color sub-pixel P3 and the first-color sub-pixel P1, and may be smaller than the width of the interval d2 between the third-color sub-pixel P3 and the second-color sub-pixel P2.

In one embodiment, when adjacent two pixel units P are arranged in a mirror image, the width of the interval between the adjacent third-color sub-pixels P3 in the adjacent two pixel units P may be substantially small, and may be smaller than the width of the interval between the third-color sub-pixel P3 and any other sub-pixel in the same pixel unit P. Therefore, the adjacent two third-color sub-pixels P3 may share the same opening of the mask for vapor deposition, which may facilitate to increase the pixel opening area of the third-color sub-pixel P3 to simplify the manufacturing process of the third-color sub-pixel P3.

In one embodiment, referring to FIG. 8 and FIG. 9, in the two pixel units P that are arranged in a mirror image, the adjacent third-color sub-pixels P3 may have the same shape, and the third-color sub-pixels P3 may have an isosceles right triangle shape.

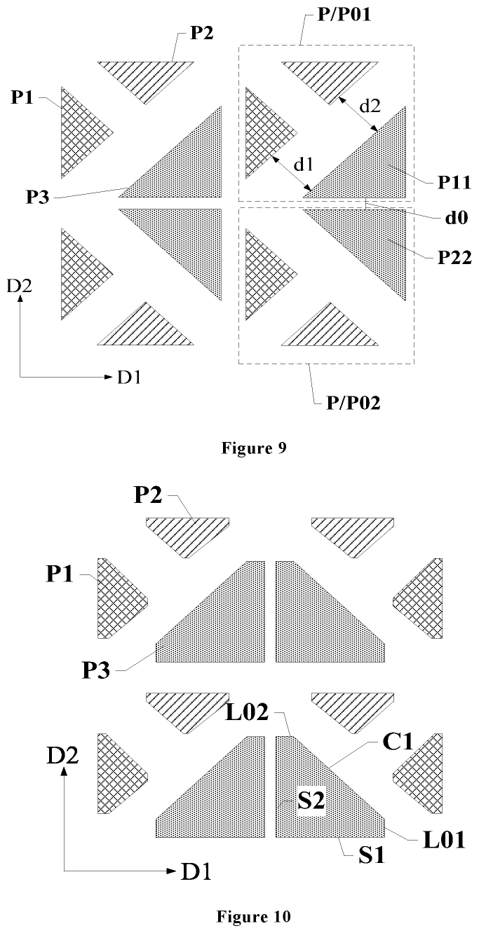

FIG. 10 illustrates a schematic diagram of arrangement of pixels of another display panel consistent with disclosed embodiments of the present disclosure. In another embodiment, referring to FIG. 10, the third-color sub-pixel P3 may include a first long edge Cl, a first side edge S1 and a second side edge S2 that are connected and perpendicular to each other, and a first connecting edge L01 and a second connecting edge L02. The first connecting edge L01 may connect a first end of the first long edge Cl and the first side edge S1, and the second connecting edge L02 may connect a second end of the first long edge Cl and the second side edge S2. The first long edge Cl may be the longest edge of the third-color sub-pixel P3.

In one embodiment, in the embodiments associated with FIG. 8 and FIG. 9, in the two pixel units P that are arranged in a mirror image, the adjacent third-color sub-pixels P3 may have an isosceles right triangle shape. One of the right-angle edges of each of the adjacent two third-color sub-pixels P3 may be adjacent to each other. When the third-color sub-pixels are formed by vapor deposition in the manufacturing process, the adjacent two third-color sub-pixels may share the same mask opening for vapor deposition. Therefore, the vapor-deposited material may be fully filled in the corner space of the isosceles right triangle, which may facilitate to improve the overall aperture ratio of the display panel.

In the schematic diagram of arrangement of pixels in the embodiment associated with FIG. 10, the adjacent third-color sub-pixels P3 may have a pentagonal structure, which may be regarded as a shape obtained by cutting two acute angles of an isosceles right triangle. Considering that when forming an opening on the mask, if the shape of the opening includes an angle formed by two straight edges, the smaller the angle is, the more difficult the mask manufacturing process is. In the embodiment associated with FIG. 10, the substantially small acute angle in the isosceles right triangle may be eliminated, such that the angle between the adjacent two edges may be greater than or equal to 90 degrees, which may facilitate to reduce the difficulty of the manufacturing process of the mask, and may facilitate to improve the overall production efficiency of the display panel.

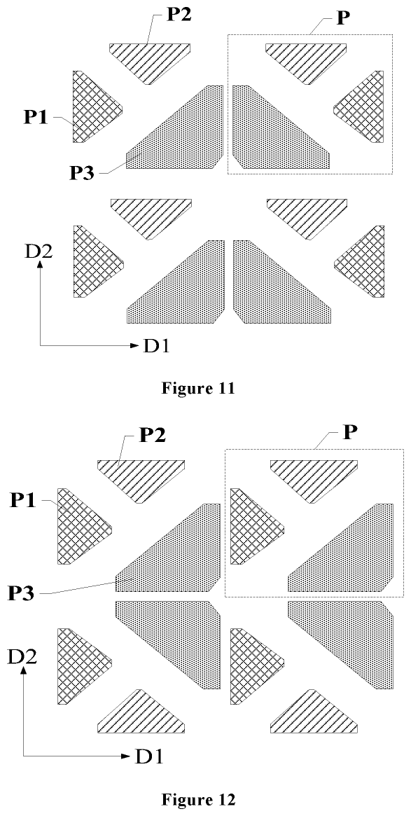

In certain embodiments, when the adjacent sub-pixels along the first direction D1 or the second direction D2 are arranged in a mirror image, the shape of the sub-pixel in the pixel unit P may include the shape illustrated in FIG. 11 or FIG. 12, which may be similar to the shape obtained by cutting angles of the isosceles right triangle. FIG. 11 illustrates a schematic diagram of arrangement of pixels of another display panel consistent with disclosed embodiments of the present disclosure; and FIG. 12 illustrates a schematic diagram of arrangement of pixels of another display panel consistent with disclosed embodiments of the present disclosure.

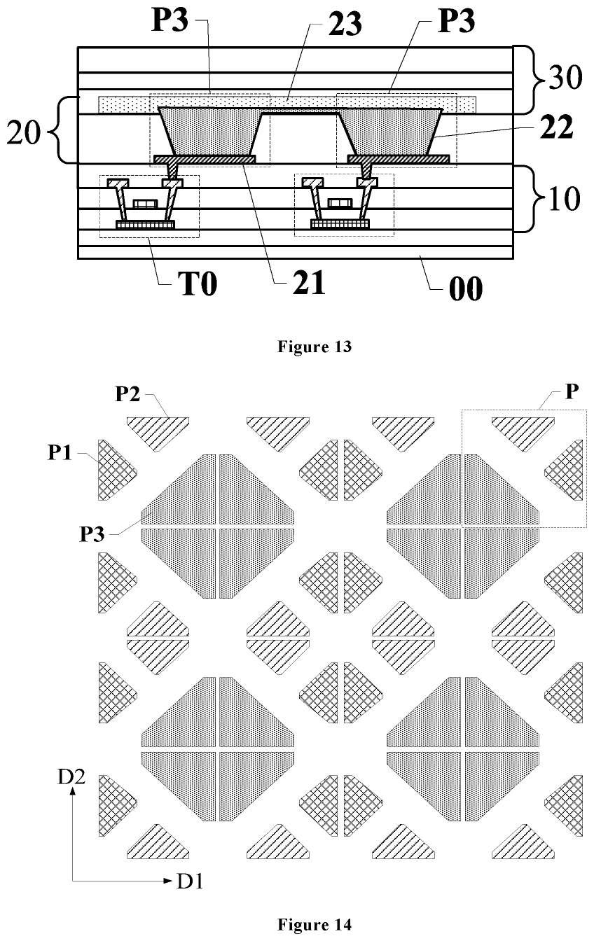

FIG. 13 illustrates a schematic diagram of film layers of a display panel consistent with disclosed embodiments of the present disclosure. Referring to FIG. 13, in one embodiment, in the two pixel units P that are arranged in a mirror image, light-emitting layers 22 of the adjacent third-color sub-pixels P3 may be connected to each other.

It should be noted that FIG. 13 may merely illustrate the film layer structures corresponding to two adjacent third-color sub-pixels P3 in the display panel, and may not represent the number and size of the film layers actually included in the display panel. In one embodiment, the display panel may include a substrate 00, an array layer 10 disposed on the substrate 00, a light-emitting element layer 20 disposed on a side of the array layer 10 facing away from the substrate 00, and an encapsulation layer 30 disposed on a side of the light-emitting element layer 20 facing away from the substrate 00. The light-emitting element layer 20 may include an anode 21, the light-emitting layer 22 and a cathode 23. The light-emitting layer 22 may be formed by evaporation. The array layer 10 may include a plurality of transistors T0, and at least a portion of the transistors TO may be electrically connected to the anode 21 of the light-emitting element layer.

Referring to FIGS. 8-12, in the two pixel units P that are arranged in a mirror image, the light-emitting layers 22 of the adjacent third-color sub-pixels P3 may be connected to each other. In other words, the light-emitting layers 22 of the adjacent two third-color sub-pixels P3 may be formed by vapor deposition using a same mask opening. Therefore, the size of the opening on the mask required for forming the light-emitting layer 22 by vapor deposition may increase, which may reduce the number of openings of the metal mask used in the manufacturing process of the light-emitting layer 22 by vapor deposition, and may avoid the reduction of the strength of the metal mask caused by the excessive number of openings and the too small size, thereby improving the strength of the metal mask. It should be noted that because the connecting portions of the light-emitting layers 22 of the adjacent two third-color sub-pixels P3 are not in contact with the anode 21 of the corresponding third-color sub-pixel, the connecting portion may not emit light, and, thus, may not affect normal light emission of the two third-color sub-pixels P3.

Referring to FIG. 13, in one embodiment, in the two pixel units P that are arranged in a mirror image, the adjacent third-color sub-pixels P3 may be electrically connected to different pixel driving circuits, respectively.

FIG. 13 may merely illustrate the transistor TO connected to the anode 21 of the light-emitting element layer. In one embodiment, the transistor TO may be the driving transistor T0 in the driving circuit. It should be understood that the driving circuit may also include a plurality of other transistors. In one embodiment, the driving circuit may be embodied as a 7T1C driving circuit or an 8T1C driving circuit in the related art, or may be any other feasible driving circuit, which may not be limited by the present disclosure.

In one embodiment, referring to FIGS. 8-13, when the light-emitting layers 22 of adjacent two third-color sub-pixels P3 in the two pixel units P that are arranged in a mirror image are connected to each other, the anodes 21 of the two third-color sub-pixels P3 may be independent and insulated from each other, and the anodes 21 of different third-color sub-pixels P3 may be connected to different driving circuits. In other words, each third-color sub-pixel P3 may be driven by an independent driving circuit for emitting light. In view of this, the control flexibility of each third-color sub-pixel P3 may be improved, which may meet the display requirements of the display panel for different pictures.

FIG. 14 illustrates a schematic diagram of arrangement of pixels of another display panel consistent with disclosed embodiments of the present disclosure. Referring to FIG. 14, in one embodiment, the sub-pixels in the adjacent two pixel units P along the first direction D1 may be arranged in a mirror image, and the sub-pixels in the adjacent two pixel units P along the second direction D2 may be arranged in a mirror image. The third-color sub-pixels P3 in the pixel units P that are arranged in a mirror image may be adjacent to each other.

FIG. 14 illustrates a schematic diagram in which the two adjacent pixel units P along the first direction D1 and the adjacent two pixel units P along the second direction D2 may be arranged in a mirror image. In view of this, the four third-color sub-pixels P3 in the top, bottom, left and right adjacent four pixel units P may be adjacent to each other. The width of the interval between the adjacent two third-color sub-pixels P3 among the four third-color sub-pixels P3 in the four pixel units P may be smaller than the width of the interval between the third-color sub-pixel P3 and any other color sub-pixel in the pixel unit P. The four third-color sub-pixels P3 may share the same mask opening for evaporation. Such arrangement of pixels may facilitate to increase the size of the opening in the mask, may facilitate to reduce the number of openings of the metal mask used in the manufacturing process, and may avoid the reduction of the strength of the metal mask caused by the excessive number of openings and the too small size, thereby improving the strength of the metal mask.

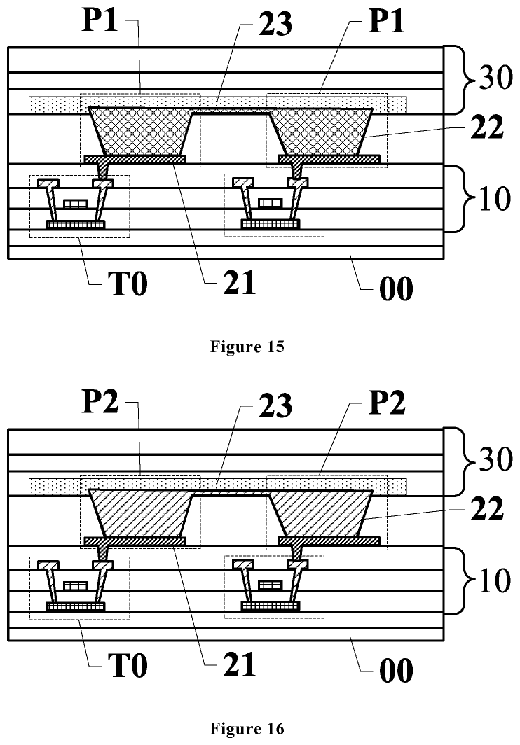

FIG. 15 illustrates a schematic diagram of film layers of another display panel consistent with disclosed embodiments of the present disclosure. Referring to FIG. 14 and FIG. 15, in one embodiment, in a portion of adjacent pixel units P along the first direction D1, two first-color sub-pixels P1 may be adjacent to each other, and the light-emitting layers 22 of the adjacent two first-color sub-pixels P1 may be connected to each other.

In one embodiment, when adjacent pixel units P along the first direction D1 are arranged in a mirror image, two first-color sub-pixels P1 in at least a portion of adjacent pixel units P may be adjacent, and the light-emitting layers 22 of the adjacent two first-color sub-pixels P1 may be connected to each other. In other words, the light-emitting layers 22 of the adjacent two first-color sub-pixels P1 may be formed by vapor deposition using a same mask opening. Therefore, the size of the opening on the mask required for forming the first-color sub-pixels P1 by vapor deposition may increase, which may reduce the number of openings of the metal mask, and may avoid the reduction of the strength of the metal mask caused by the excessive number of openings and the too small size, thereby improving the strength of the metal mask. It should be noted that because the connecting portions of the light-emitting layers 22 of the adjacent two first-color sub-pixels P1 are not in contact with the anode 21 of the corresponding first-color sub-pixel, the connecting portion may not emit light, and, thus, may not affect normal light emission of the two first-color sub-pixels P1.

FIG. 16 illustrates a schematic diagram of film layers of another display panel consistent with disclosed embodiments of the present disclosure. Referring to FIG. 14 and FIG. 16, in one embodiment, in a portion of adjacent pixel units P along the second direction D2, two second-color sub-pixels P2 may be adjacent to each other, and the light-emitting layers 22 of the adjacent two second-color sub-pixels P2 may be connected to each other.

In one embodiment, when adjacent pixel units P along the second direction D2 are arranged in a mirror image, two second-color sub-pixels P2 in at least a portion of adjacent pixel units P may be adjacent, and the light-emitting layers 22 of the adjacent two second-color sub-pixels P2 may be connected to each other. In other words, the light-emitting layers 22 of the adjacent two second-color sub-pixels P2 may be formed by vapor deposition using a same mask opening. Therefore, the size of the opening on the mask required for forming the second-color sub-pixels P2 by vapor deposition may increase, which may reduce the number of openings of the metal mask, and may avoid the reduction of the strength of the metal mask caused by the excessive number of openings and the too small size, thereby improving the strength of the metal mask. It should be noted that because the connecting portions of the light-emitting layers 22 of the adjacent two second-color sub-pixels P2 are not in contact with the anode 21 of the corresponding second-color sub-pixel, the connecting portion may not emit light, and, thus, may not affect normal light emission of the two second-color sub-pixels P2.

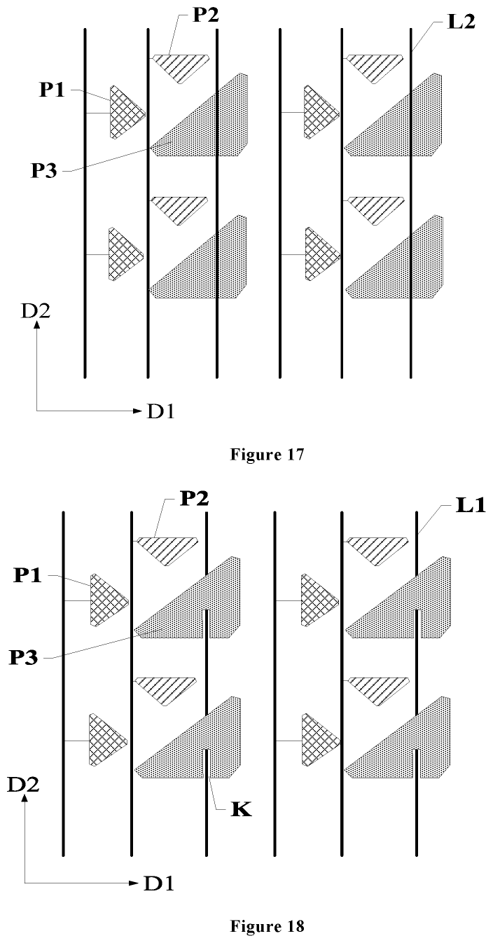

FIG. 17 illustrates a schematic top view of sub-pixels and data lines in a display panel consistent with disclosed embodiments of the present disclosure. Referring to FIG. 17, in one embodiment, along a thickness direction of the display panel, at least a portion of the sub-pixels may not overlap with the data lines L2.

In one embodiment, when arranging the sub-pixels and the data lines L2 in the display panel, at least a portion of the sub-pixels and the data lines L2 may be staggered, such that the anodes 21 of at least the portion of the sub-pixels may not overlap with the data lines L2. Referring to FIG. 17, the anodes 21 of both the first-color sub-pixel P1 and the second-color sub-pixel P2 may not overlap with the data lines L2, such that the coupling capacitance between the data lines L2 and the anodes of the sub-pixels may be reduced, which may prevent the signal on the data line L2 from affecting the signals on the anodes 21 of the sub-pixels, and may facilitate to ensure the display accuracy of the sub-pixels. It should be noted that in the actual film layer structure, for example, referring to FIG. 16, the data line L2 (formed in a same layer as the source and drain of the transistor TO) may be located on the side of the anode 21 of the sub-pixel facing towards the substrate 00.

In one embodiment, when actually laying out the sub-pixels and the data lines L2, the data lines L2 may be evenly arranged in the display region. When the width along the first direction D1 of the third-color sub-pixel P3 with a substantially large pixel opening area is larger than the spacing between adjacent data lines L2, along the thickness direction of the display panel, the third-color sub-pixel P3 with a substantially large pixel opening area may inevitably overlap with a portion of the data lines L2. In view of this, the shape of the third-color sub-pixel P3 may be converted, and a certain hollow K may be formed on the third-color sub-pixel P3, and the hollow K may also be formed at the same position of the anode 21 of the sub-pixel.

FIG. 18 illustrates a schematic top view of sub-pixels and data lines in a display panel consistent with disclosed embodiments of the present disclosure. In one embodiment, referring to FIG. 18, the hollow K and the data line L2 may overlap with each other along the thickness direction of the display panel, and, thus, the overlapping area between the data line L2 and the anode 21 of the third-color sub-pixel P3 with a substantially large pixel opening area may be reduced, which may facilitate to reduce the coupling capacitance between the anode 21 of the third-color sub-pixel P3 and the data line L2, to reduce the influence of the signal on the data line L2 on the potential of the anode 21 of the third-color sub-pixel P3, and to ensure the display accuracy of the third-color sub-pixels P3 to a certain extent.

It should be noted that although FIG. 17 illustrates a relative positional relationship between the data lines L2 and the sub-pixels in the pixel unit P, in a direction perpendicular to a light-emitting surface of the display panel, the data line L2 may at least partially overlap with the sub-pixel in the pixel unit P. In the actual film layer structure, the data line L2 may be located on the side of the sub-pixel facing away from the light-emitting surface of the display panel, such that the data line L2 may not block the opening of the sub-pixel, and may not affect the screen-to-body ratio of the display panel.

Referring to FIG. 17 and FIG. 18, in one embodiment, sub-pixels with a same color and located in a same column along the second direction D2 may be connected to a same data line L2.

In one embodiment, in the disclosed display panel, a plurality of sub-pixels with the same color may be located in the same column, and sub-pixels with different colors may form a plurality of sub-pixel columns with different colors. The sub-pixels with the same color located in the same column may be connected to the same data line L2, and the sub-pixels located in different columns may be respectively connected to different data lines L2. The sub-pixels with the same color located in the same column may share the same data line L2, which may facilitate to reduce the number of data lines L2 actually contained in the display panel, and may facilitate to simplify the wiring complexity of the display panel.

In one embodiment, the first-color sub-pixel P1 may be a green sub-pixel, the second-color sub-pixel P2 may be a red sub-pixel, and the third-color sub-pixel P3 may be a blue sub-pixel.

Limited by the characteristics of the luminescent materials corresponding to the sub-pixels with different colors, the lifespan of the blue luminescent material may be substantially low, and the lifespan of the red luminescent material and the green luminescent material may be substantially high. In the disclosed embodiments, the pixel opening area of the blue sub-pixel with substantially low lifespan may be set to be the largest, to balance the lifespan difference between the blue sub-pixel and the red sub-pixel as well as the green sub-pixel, which may facilitate to prolong the service life of the display panel.

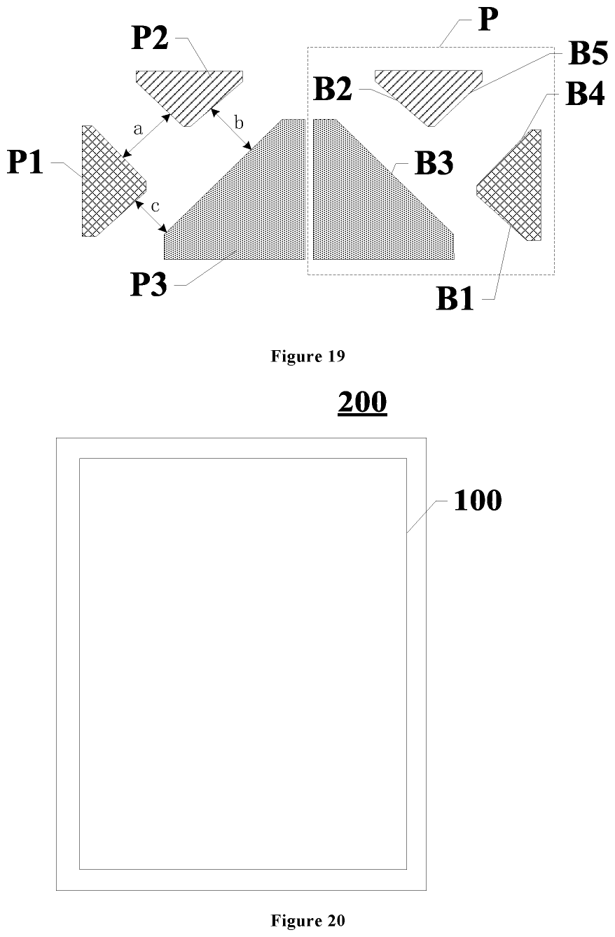

FIG. 19 illustrates a schematic diagram of arrangement of three sub-pixels in a same pixel unit. Referring to FIG. 19, in one embodiment, in the same pixel unit P, a minimum distance between the first-color sub-pixel P1 and the second-color sub-pixel P2 may be marked as “a”, a minimum distance between the third-color sub-pixel P3 and the second-color sub-pixel P2 may be marked as “b”, and a minimum distance between the first-color sub-pixel P1 and the third-color sub-pixel P3 may be marked as “c”, where a=b≥c.

Referring to FIG. 19, in one embodiment, the first-color sub-pixel P1 may be a green sub-pixel, the second-color sub-pixel P2 may be a red sub-pixel, and the third-color sub-pixel P3 may be a blue sub-pixel. The minimum distance between the green sub-pixel and the red sub-pixel may be marked as “a”, the minimum distance between the red sub-pixel and the blue sub-pixel may be marked as “b”, and the minimum distance between the green sub-pixel and the blue sub-pixel may be marked as “c”. Considering that the wavelength of red light corresponding to the red sub-pixel is substantially large, when actually forming the red sub-pixel, a thickness of the light-emitting layer of the red sub-pixel may be set to be larger than a thickness of the light-emitting layers of the green sub-pixel and the blue sub-pixel. The width of the interval between the red sub-pixel and the green pixel and the width of the interval between the red sub-pixel and the blue sub-pixel may increase, which may facilitate to increase the process margin and to improve the process yield.

Referring to FIG. 19, in one embodiment, in the same pixel unit P, at least one edge of the first-color sub-pixel P1 may be parallel to one edge of the second-color sub-pixel P2, and at least one edge of the first-color sub-pixel P1 may be parallel to one edge of the third-color sub-pixel P3. In the same pixel unit P, in the adjacent sub-pixels with two colors, two edges that are parallel to each other may be adjacent to each other.

In one embodiment, in the same pixel unit P, adjacent two edges in adjacent two sub-pixels may be arranged in parallel. For example, the edge B1 of the first-color sub-pixel P1 and the edge B2 of the second-color sub-pixel P2 may be adjacent and parallel to the edge B3 of the third-color sub-pixel P3. The edge B4 of the first-color sub-pixel P1 may be adjacent and parallel to the edge B5 of the second-color sub-pixel P2. An extension direction of the edges that are disposed in parallel may intersect the first direction D1 and the second direction D2. Such arrangement of the sub-pixels in the pixel unit P may facilitate to improve the space utilization rate of the pixel unit P, may facilitate to improve the pixel aperture ratio of the display panel, and, thus, may facilitate to improve the display effect of the display panel.

The present disclosure also provides a display device. FIG. 20 illustrates a schematic diagram of a display device consistent with disclosed embodiments of the present disclosure. Referring to FIG. 20, the display device 200 may include any one of the above-disclosed display panels 100.

It should be understood that the disclosed display device 200 may include a mobile phone, a tablet, a computer, a TV, a vehicle-mounted display device, or any other display device with display functions, which may not be limited by the present disclosure. The disclosed display device may have the beneficial effects of the disclosed display panel, and may refer to the specific description of the disclosed display panel, which may not be repeated herein.

The disclosed embodiments may have following beneficial effects. The disclosed display panel and display device may include a plurality of pixel units arranged in an array along the first direction and the second direction. The same pixel unit may include three sub-pixels with different emission colors. The pixel opening area of the third-color sub-pixel may be larger than the pixel opening areas of both the first-color sub-pixel and the second-color sub-pixel. Along the first direction, the third-color sub-pixel may overlap with the first-color sub-pixel, and may not overlap with the second-color sub-pixel. Along the second direction, the third-color sub-pixel may overlap with the second-color sub-pixel and may not overlap with the first-color sub-pixel. In view of such arrangement, the arrangement of the three sub-pixels in the same pixel unit may be substantially compact. Compared with the arrangement where the three sub-pixels in the pixel unit are arranged in a same column or in a same row, the disclosed arrangement of sub-pixels may improve the aperture ratio and screen-to-body ratio of the display panel, and may further facilitate to improve the display quality.

In addition, in the same pixel unit, each sub-pixel may include a longest edge. The extension direction of the longest edge of the first-color sub-pixel may be along the second direction, and the longest edge of the first-color sub-pixel may be located on the side of the other edges of the first-color sub-pixel away from the geometric center of the region where the pixel unit is located. The extension direction of the longest edge of the second-color sub-pixel may be along the first direction, and the longest edge of the second-color sub-pixel may be located on the side of the other edges of the second-color sub-pixel away from the geometric center of the region where the pixel unit is located. The extension direction of the longest edge of the third-color sub-pixel may intersect the first direction and the second direction, and the longest edge of the third-color sub-pixel may be located on the side of the other edges of the third-color sub-pixel facing towards the geometric center of the region where the pixel unit is located. In such arrangement, the longest edge of the first-color sub-pixel, the longest edge of the second-color sub-pixel, and the other edges except for the longest edge of the third-color sub-pixel may together form an outline of the pixel unit. Such arrangement may also facilitate to improve the arrangement compactness of the three sub-pixels of the pixel unit, which may facilitate to further improve the aperture ratio and screen-to-body ratio of the display panel, thereby further improving the display quality.

The description of the disclosed embodiments is provided to illustrate the present disclosure to those skilled in the art. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments illustrated herein but is to be accorded the widest scope consistent with the principles and novel features disclosed herein.

What is claimed is:

1. A display panel, comprising:
a plurality of scanning lines and a plurality of data lines, wherein the plurality of scanning lines are extended along a first direction and arranged along a second direction, the plurality of data lines are extended along the second direction and arranged along the first direction, and the first direction intersects the second direction; and
a plurality of pixel units arranged in an array along the first direction and the second direction, wherein:
a pixel unit of the plurality of pixel units includes three sub-pixels, the three sub-pixels include a first-color sub-pixel, a second-color sub-pixel and a third-color sub-pixel, respectively, and the first color, the second color and the third color are different from each other,
a pixel opening area of the third-color sub-pixel is larger than a pixel opening area of the first-color sub-pixel, and is larger than a pixel opening area of the second-color sub-pixel,
along the first direction, the third-color sub-pixel overlaps with the first-color sub-pixel and does not overlap with the second-color sub-pixel, and along the second direction, the third-color sub-pixel overlaps with the second-color sub-pixel and does not overlap with the first-color sub-pixel,
each of the first-color sub-pixel, the second-color sub-pixel and the third-color sub-pixel has a polygon shape with a longest edge,
an extension direction of the longest edge of the first-color sub-pixel is along the second direction, an extension direction of the longest edge of the second-color sub-pixel is along the first direction, and an extension direction of the longest edge of the third-color sub-pixel intersects the first direction and the second direction, and
the longest edge of the first-color sub-pixel is located on a side of other edges of the first-color sub-pixel facing away from a geometric center of a region where the pixel unit is located, the longest edge of the second-color sub-pixel is located on a side of other edges of the second-color sub-pixel facing away from the geometric center of the region where the pixel unit is located, and the longest edge of the third-color sub-pixel is located on a side of other edges of the third-color sub-pixel facing towards the geometric center of the region where the pixel unit is located.

2. The display panel according to claim 1, wherein:
in the pixel unit, each of the first-color sub-pixel, the second-color sub-pixel and the third-color sub-pixel has a convex polygon shape.

3. The display panel according to claim 2, wherein:
in the pixel unit, the first-color sub-pixel, the second-color sub-pixel and the third-color sub-pixel have a same shape.

4. The display panel according to claim 2, wherein:
in the pixel unit, the first-color sub-pixel, the second-color sub-pixel and the third-color sub-pixel have any one of a triangle shape, a trapezoid shape, and a hexagon shape.

5. The display panel according to claim 2, wherein:
in the pixel unit, each of the first-color sub-pixel, the second-color sub-pixel and the third-color sub-pixel has an isosceles right triangular shape.

6. The display panel according to claim 2, wherein:
in the pixel unit, at least part of the three sub-pixels includes:
a first edge and a second edge that are disposed in parallel,
a first side waist and a second side waist that are respectively connected with two ends of the first edge, and
a first connecting edge and a second connecting edge,
wherein the first connecting edge connects the first side waist and a first end of the second edge, the second connecting edge connects the second side waist and a second end of the second edge, and the second edge is the longest edge of the at least one of the three sub-pixels.

7. The display panel according to claim 1, wherein:
the three sub-pixels in adjacent two pixel units along the first direction are arranged in a mirror image; or
the three sub-pixels in adjacent two pixel units along the second direction are arranged in a mirror image, wherein the third-color sub-pixels in the two pixel units that are arranged in a mirror image are adjacent to each other.

8. The display panel according to claim 1, wherein:
the three sub-pixels in adjacent two pixel units along the first direction are arranged in a mirror image, and/or
the three sub-pixels in adjacent two pixel units along the second direction are arranged in a mirror image,
the two pixel units that are arranged in a mirror image include a first pixel unit and a second pixel unit, respectively,
a first sub-pixel in the first pixel unit is adjacent to a second sub-pixel in the second pixel unit, and
a width of an interval between the first sub-pixel and the second sub-pixel is smaller than a width of an interval between the first sub-pixel and any other sub-pixel in the first pixel unit, and is smaller than a width of an interval between the second sub-pixel and any other sub-pixel in the second pixel unit.

9. The display panel according to claim 7, wherein:
in the two pixel units that are arranged in the mirror image, the adjacent third-color sub-pixels have a same shape, wherein:
each of the adjacent third-color sub-pixels has an isosceles right triangle shape, or
each of the adjacent third-color sub-pixels includes a first long edge, a first side edge and a second side edge that are connected and perpendicular to each other, a first connecting edge and a second connecting edge, wherein the first connecting edge connects a first end of the first long edge and the first side edge, the second connecting edge connects a second end of the first long edge and the second side edge, and the first long edge is the longest edge of the third-color sub-pixel.

10. The display panel according to claim 7, wherein:
in the two pixel units that are arranged in the mirror image, light-emitting layers of the adjacent third-color sub-pixels are continuous.

11. The display panel according to claim 7, wherein:
in the two pixel units that are arranged in the mirror image, the adjacent third-color sub-pixels are electrically connected to different pixel driving circuits, respectively.

12. The display panel according to claim 1, wherein:
the three sub-pixels in adjacent two pixel units along the first direction are arranged in a mirror image; and
the three sub-pixels in adjacent two pixel units along the second direction are arranged in a mirror image, wherein third-color sub-pixels in the pixel units that are arranged in a mirror image are adjacent to each other.

13. The display panel according to claim 12, wherein:
in a portion of adjacent pixel units along the first direction, two first-color sub-pixels are adjacent to each other, and light-emitting layers of the adjacent two first-color sub-pixels are continuous.

14. The display panel according to claim 12, wherein:
in a portion of adjacent pixel units along the second direction, two second-color sub-pixels are adjacent to each other, and light-emitting layers of the adjacent two second-color sub-pixels are continuous.

15. The display panel according to claim 1, wherein:
along a thickness direction of the display panel, at least one of the first-color sub-pixel, the second-color sub-pixel and the third-color sub-pixel does not overlap with the plurality of data lines.

16. The display panel according to claim 1, wherein:
sub-pixels with a same color and located in a same column along the second direction are connected to a same data line of the plurality of data lines.

17. The display panel according to claim 1, wherein:
the first-color sub-pixel is a green sub-pixel, the second-color sub-pixel is a red sub-pixel, and the third-color sub-pixel is a blue sub-pixel.

18. The display panel according to claim 17, wherein:
in the pixel unit, a minimum distance between the first-color sub-pixel and the second-color sub-pixel is marked as “a”, a minimum distance between the third-color sub-pixel and the second-color sub-pixel is marked as “b”, and a minimum distance between the first-color sub-pixel and the third-color sub-pixel is marked as “c”, wherein a=b≥c.

19. The display panel according to claim 1, wherein:
in the pixel unit, at least one edge of the first-color sub-pixel is parallel to one edge of the second-color sub-pixel, and at least one edge of the first-color sub-pixel is parallel to one edge of the third-color sub-pixel; and
in the pixel unit, in adjacent sub-pixels with two colors, two edges that are parallel to each other are adjacent.

20. A display device, comprising:
a display panel, the display panel including:
a plurality of scanning lines and a plurality of data lines, wherein the plurality of scanning lines are extended along a first direction and arranged along a second direction, the plurality of data lines are extended along the second direction and arranged along the first direction, and the first direction intersects the second direction; and
a plurality of pixel units arranged in an array along the first direction and the second direction, wherein:
a pixel unit of the plurality of pixel units includes three sub-pixels, the three sub-pixels include a first-color sub-pixel, a second-color sub-pixel and a third-color sub-pixel, respectively, and the first color, the second color and the third color are different from each other,
a pixel opening area of the third-color sub-pixel is larger than a pixel opening area of the first-color sub-pixel, and is larger than a pixel opening area of the second-color sub-pixel,
along the first direction, the third-color sub-pixel overlaps with the first-color sub-pixel and does not overlap with the second-color sub-pixel, and along the second direction, the third-color sub-pixel overlaps with the second-color sub-pixel and does not overlap with the first-color sub-pixel,
each of the first-color sub-pixel, the second-color sub-pixel and the third-color sub-pixel has a polygon shape with a longest edge,
an extension direction of the longest edge of the first-color sub-pixel is along the second direction, an extension direction of the longest edge of the second-color sub-pixel is along the first direction, and an extension direction of the longest edge of the third-color sub-pixel intersects the first direction and the second direction, and
the longest edge of the first-color sub-pixel is located on a side of other edges of the first-color sub-pixel facing away from a geometric center of a region where the pixel unit is located, the longest edge of the second-color sub-pixel is located on a side of other edges of the second-color sub-pixel facing away from the geometric center of the region where the pixel unit is located, and the longest edge of the third-color sub-pixel is located on a side of other edges of the third-color sub-pixel facing towards the geometric center of the region where the pixel unit is located.
